(19) United States
(12) Patent Application Publication
(10) Pub. No.: US 2020/0404805 A1
(43) Pub. Date: Dec. 24, 2020

(54) ENHANCED COOLING DEVICE

(71) Applicant: Baidu USA LLC, Sunnyvale, CA (US)

(72) Inventor: Tianyi Gao, Sunnyvale, CA (US)

(21) Appl. No.: 16/445,876

(22) Filed: Jun. 19, 2019

(51) Int. Cl. H05K 7/20; F28D 15/02; H01L 23/427

(52) U.S. Cl. CPC H05K 7/20336; F28D 15/02; H05K 7/20309; H05K 7/20736; H05K 7/20318; H01L 23/427; H05K 7/20818; H05K 7/20327

(57) ABSTRACT

A cooling device can include an evaporation chamber in fluid connection with a condensing chamber through one or more vapor channels and one or more liquid channels, the evaporation chamber being at a bottom of the cooling device and the condensing chamber being above the evaporation chamber. A cooling member of the device can be thermally connected to and located above the condensing chamber or the condensing chamber and cooling member can be designed as one unit. A fluid can be disposed and trapped in the connected chambers to undergo phase changes due to heat transfer. During operation, the fluid extracts heat and changes phase from liquid to vapor. The vapor travels up the one or more vapor channels into the condensing chamber where the vapor is cooled and changes phase to liquid. The liquid travels down the one or more liquid channels back to the evaporation chamber.

### TECHNICAL FIELD

Embodiments of the present disclosure relate generally to a cooling device. More particularly, embodiments of the disclosure relate to a cooling device for electronic systems that utilizes phase change of a fluid.

### BACKGROUND

Electronic circuits, including processors, semiconductors, and passive components, generate heat during operation. Heat sinks, cold plates, two-phase cold plates, and heat pipes vapor chamber are among the various devices and techniques that are placed on electronic components and housings to transfer heat.

Passive heat sinks (e.g., air-cooled heat sinks) typically have relatively low heat transfer coefficient that can be insufficient for high power density cooling applications.

Heat pipes, which use a wick structure in a pipe, can be limited by structural design—the diameter of the heat pipe is proportional to the heat transfer performance of the heat pipe. Thus, the heat pipe geometry may make it unsuitable for some applications, for example, when a compact design and package is desired.

Cold plate devices provide high power density thermal management, but there are limitations and drawbacks. Cold plates contain a cooling liquid which require liquid piping for fluid supply and return. A pump is attached to circulate the fluid. The fluid transmission pipes and pump can be inherently unreliable and prone to failure.

Cooling devices for high power density situations can require a cooling device that attaches directly to a chip or high power density electronics and an external cooling system, for example, a heat exchanger or a cooling fluid loop. Another method for better heat transfer coefficient in high power density cooling is using larger heat transfer area device.

There is a need for cooling technology that addresses the drawbacks and deficiencies described, especially for high heat flux cooling. A compact design for cooling device is also a key consideration, since the space is very limited on a board especially surrounding a high performance chip, such as high band width (HBM), voltage regulator (VR), and so on. Therefore, the reduced space near the chip or on the board requires that a cooling device or cooling module be properly installed and sufficiently robust. A compact design is a feasible solution.

### BRIEF DESCRIPTION OF THE DRAWINGS

Embodiments of the invention are illustrated by way of example and not limited in the figures of the accompanying drawings in which like references indicate similar elements.

FIG. 1 shows a cooling device with separate vaporizing chamber and condensing chamber, according to one embodiment.

FIG. 2 shows a cooling device with vaporizing chamber and condensing chamber in a single housing, according to one embodiment.

FIG. 3 shows a cooling device with sloped condenser and wicking structure, according to one embodiment.

FIG. 4 shows a cooling device with sloped condenser and wicking structure, according to one embodiment.

FIGS. 5 and 6 show a cooling device with enhanced condenser geometry, according to some embodiments.

FIG. 7 shows cooling device with cooling plate, according to one embodiment.

FIG. 8 shows a process for producing a cooling device, according to one embodiment.

FIG. 9 shows an example of an electronic rack according to one embodiment.

### DETAILED DESCRIPTION

Various embodiments and aspects of the inventions will be described with reference to details discussed below, and the accompanying drawings will illustrate the various embodiments. The following description and drawings are illustrative of the invention and are not to be construed as limiting the invention. Numerous specific details are described to provide a thorough understanding of various embodiments of the present invention. However, in certain instances, well-known or conventional details are not described in order to provide a concise discussion of embodiments of the present inventions.

Reference in the specification to “one embodiment” or “an embodiment” means that a particular feature, structure, or characteristic described in conjunction with the embodiment can be included in at least one embodiment of the invention. The appearances of the phrase “in one embodiment” in various places in the specification do not necessarily all refer to the same embodiment.

### General

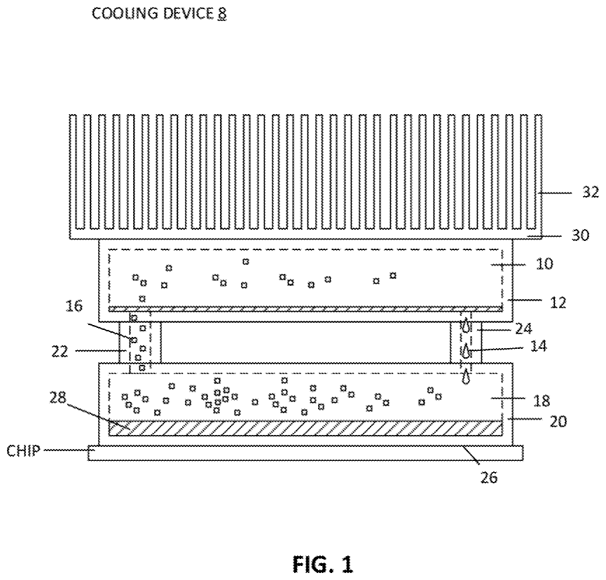

A cooling device (e.g., shown in FIGS. 1-7) can combine a heat exchanger or cooling system with heat sink or cold plate and achieve a high heat transfer coefficient and large heat transfer area by utilizing phase change natural convection heat transfer. For example, referring to FIG. 1, a cooling device 8 can include: an evaporation chamber 18 in fluid connection with a condensing chamber 10 through one or more vapor channels 16 (also known as ‘risers’) and one or more liquid channels 14 (also known as ‘down comers’).

The evaporation chamber is at a bottom or bottom portion of the cooling device which may directly attach to a heat source (e.g., chips). The evaporation chamber and fluid in therein can absorb heat from a chip that connects through a bottom surface 26 of the device.

A condensing chamber 10 is above the evaporation chamber (e.g., located at a top portion). The cooling device can have a cooling member 30, such as a heat sink and/or a cooling plate, thermally connected to and located above the condensing chamber (e.g., connected to the top portion).

A fluid 28, for example, a refrigerant, coolant, water, or other solution, can be disposed and trapped in the connected chambers 10 and 18 to undergo phase changes due to heat transfer. During operation, as the chip generates heat, the heat from the chip will cause the fluid in the evaporation chamber to vaporize (phase change).

Due to density difference between the vapor and liquid fluid, the vapor will rise up through the one or more vapor channels to the condensing chamber. Each of the vapor channels are larger in cross section or diameter than each of the one or more liquid channels, causing the vapor to naturally travel up the larger vapor channels to balance pressure in the connected chambers. The cooling member, located above the condensing chamber, can extract and transfer heat away from the condensing chamber and the cooling device, thereby condensing the vapor therein (turning the fluid vapor back to fluid liquid). The liquid travels down the one or more liquid channels back to the evaporation chamber, aided by gravity, during operation.

The cycle repeats with the liquid in the evaporation chamber, ready to be converted back to vapor due to heat from the chip. Beneficially, as the liquid changes to vapor, it absorbs thermal energy from the chip. Similarly, when the vapor changes back to liquid, it releases thermal energy to the cooling member and then away from the cooling device. In one aspect, the cooling device does not have a pump or any type of fluid mover to circulate fluid. This can improve reliability because pumps can be prone to failure and fluid lines can complicate a design where many components are packaged in a tight space.

As described above, the device uses thermosiphon technology (e.g., phase change natural convection) for higher heat transfer coefficient between the device and the chip. The device can circulate fluid using natural convection (using density difference and gravity) without need of a mechanical pump. The condensing chamber can have a larger heat transfer area than the bottom part to transfer the heat to the cooling member (e.g., a passive heat sink or cooling plate). This can allow a compact design and footprint at a bottom of the device to interface with and connect to a chip while maintaining high heat transfer performance, low thermal resistance, high reliability, flexibility with regard to using air cooling and/or liquid cooling, less fluid being required per unit (this can be understood as that there is no system cooling design needed, only a small amount of fluid is required to partially fill the evaporation and condensing chambers), and enabling large heat transfer area design.

### Separate Housings

In one aspect, the evaporation chamber and condensing chamber are formed in separate housings. For example, as shown in FIG. 1, an evaporation chamber 18 is formed in a first housing 20, and a condensing chamber 10 is formed in a second housing 12. The first housing is below the second housing so that gravity can aid in the cycling of liquid fluid back into the evaporation chamber. One or more vapor channels 16 are formed in one or more vapor pipes or channels 22. Similarly, one or more liquid channels 14 are formed in one or more liquid pipes or channels 24. The first housing 20 and the second housing 12 are connected through the one or more vapor pipes 22 and the one or more liquid pipes 24.

A cooling member 30 is attached to a top surface of the second housing. The cooling member can be an air-cooled heatsink with one or more fins 32 as shown FIG. 1. Fin designs can vary and be determined based on application specific situations and routine testing. In one aspect, the one or more fins 32 can be flat-shaped members that are arranged substantially parallel to each other, the size and geometry of each fin can be determined based on routine testing. Other geometries can be implemented. The cooling member can remove heat from the cooling device by absorbing the heat from the second housing 12 and transferring the heat to a fluid such as air. The fins can provide additional surface area to transfer the heat to the fluid.

### Evaporation Chamber and Condensing Chamber in Same Body

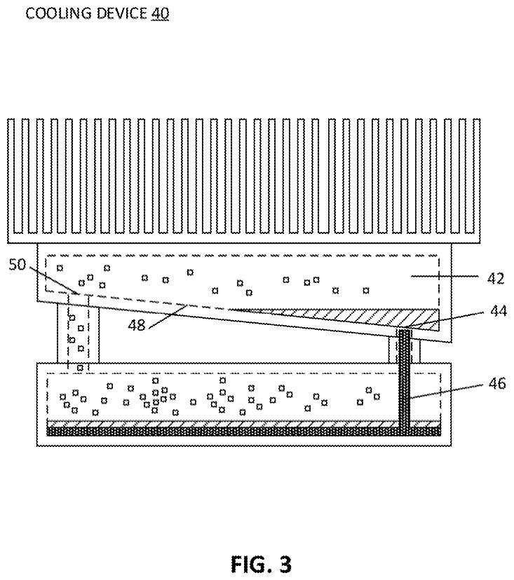

In one aspect, a cooling device can have an evaporation chamber and condensing chamber in the same body or housing. For example, cooling device 60 of FIG. 3 shows an evaporation chamber 74 and condensing chamber 68 formed in a single body or housing 74. The chambers can be separated by a separation wall 72 within the body. One or more vapor channels 66 and one or more liquid channels 70 can be formed by openings or gaps in the separation wall.

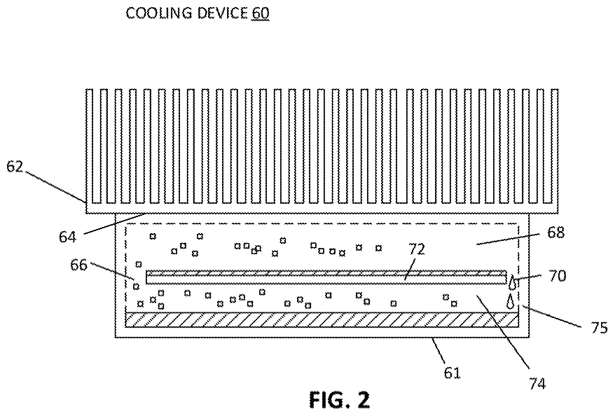

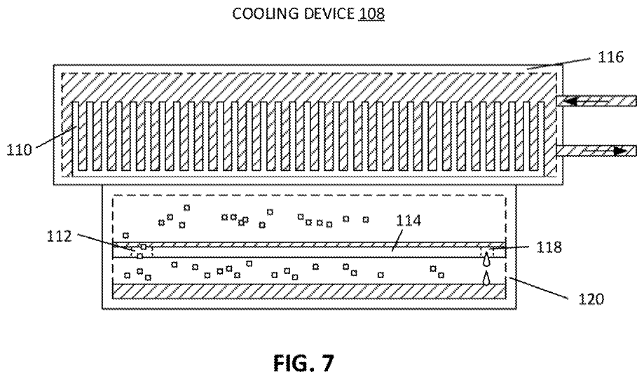

For example, FIG. 2 shows the channels being formed by gaps between the separation wall and the body. In other words, a vapor channel can be formed in a first side of the body by a gap between separation wall and the body. Similarly, the liquid channel can be formed in a second side of the housing, opposite the first side, by a gap between the separation wall and the body. Additionally or alternatively, as shown in FIG. 7, the channels can be formed by openings or perforated holes 112 and 118 in the separation wall.

Referring back now to FIG. 2, cooling member 62 can be fixed to a top surface 64 of the single body. Thus, similar to other embodiments of the present disclosure, the embodiment shown in FIG. 2 absorbs heat energy from a chip when attached at the bottom surface 61 of the device (not shown). The heat causes the trapped fluid in the device to vaporize and travel up to the condensing chamber through the vapor channels. The cooling member can transfer heat away from the condensing chamber causing the vapor in the condensing chamber to turn back into liquid and flow back to the evaporation chamber through the evaporation channels.

It should be understood that the cooling member can be designed into or integral with the housing of the condensing chamber in different embodiments. For example, in one aspect, the evaporation chamber, the condensing chamber, and the cooling member can be formed in a single body, where the evaporation chamber and the condensing chamber are separated by a separation wall within the single body, and the one or more vapor channels and the one or more liquid channels are formed by openings or gaps in the separation wall. In other words, the cooling member can be formed from the same body or housing as the condensing chamber (e.g., the cooling device of FIG. 1), or from the same body as the condensing chamber and the evaporation chamber, with known manufacturing techniques. Alternatively, the cooling member can be formed separately and fixed to the condensing chamber.

### Declined Condenser

In one aspect, the condensing chamber has a declined or tilted orientation. A floor of the condensing chamber can be horizontally tilted such that an opening of the one or more vapor channels is higher than an opening of the one or more liquid channels in the condensing chamber. The liquid can roll down the tilted condensing chamber floor towards the one or more liquid channels. Like other features, this optional feature can be present in either the single housing or separate housing embodiments.

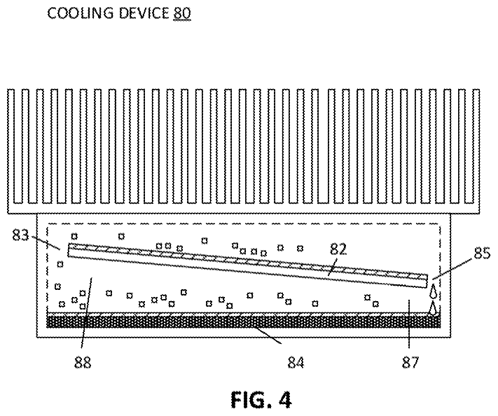

For example, FIG. 4 shows a cooling device 80 with evaporator and condenser in a single housing. The separation wall 82 can have a horizontal tilt or slope such that a top opening 83 of the one or more vapor channels is higher than a top opening of the one or more liquid channels 85. The liquid can roll down the slope of the separation wall into the one opening of the one or more liquid channels. In such design, a larger volume area 88 and smaller volume area 87 are formed in the evaporation chamber, which aids in pressure balancing and vapor flowing.

Similarly, FIG. 3 shows a cooling device 40 with separate housings for the evaporation chamber and the condensing chamber 42. The condensing chamber can have floor 48 that is horizontally tilted or sloped such that an opening 50 of the one or more vapor channels is higher than an opening 44 of the one or more liquid channels in the condensing chamber. The liquid can roll down the floor of the condensing chamber towards the one or more liquid channels.

### Wick Structure

In one aspect, the cooling device can optionally include a porous wick structure. The wick structure can utilize capillary action to help facilitate the movement of fluid between the chambers. For example, as shown in FIGS. 3 and 4, cooling devices can include a porous wick structure 46 and 84 disposed in the evaporation chamber. This can help distribute the fluid evenly in the evaporation chamber, which can eliminate hotspots especially in the heterogeneous integration scenarios where high power density chips and low density chips are packaged close to each other. Heterogeneous Integration refers to integration of separately manufactured components into an assembly to satisfy heterogeneous computing requirements. The components in the assembly work together to provide enhanced functionality and improved operating characteristics.

In addition, the porous wick structure can further disposed in the one or more liquid channels, as shown in FIG. 3, and even disposed in the condensing chamber partially, to help transport the liquid from the condensing chamber to the evaporation chamber.

### Enhanced Condenser Area

In one aspect, a condensing portion of the cooling device can optionally have an increased size or area, relative to the footprint (e.g., a bottom surface) of the cooling device. This can increase the amount of heat that can transfer from the condensing chamber to the cooling member, resulting in a faster condensing of the vapor to a liquid.

Some cooling devices are limited by the surface area of the chip and the footprint of the cooling device that makes contact with the chip. The smaller the chip surface, the less heat energy can be dissipated. With the cooling device described in the present disclosure, however, phase change of the fluid transfers heat energy from the device with a small footprint. The condensing portion can be larger than the footprint of the device and transfer heat through to the cooling member in greater amounts.

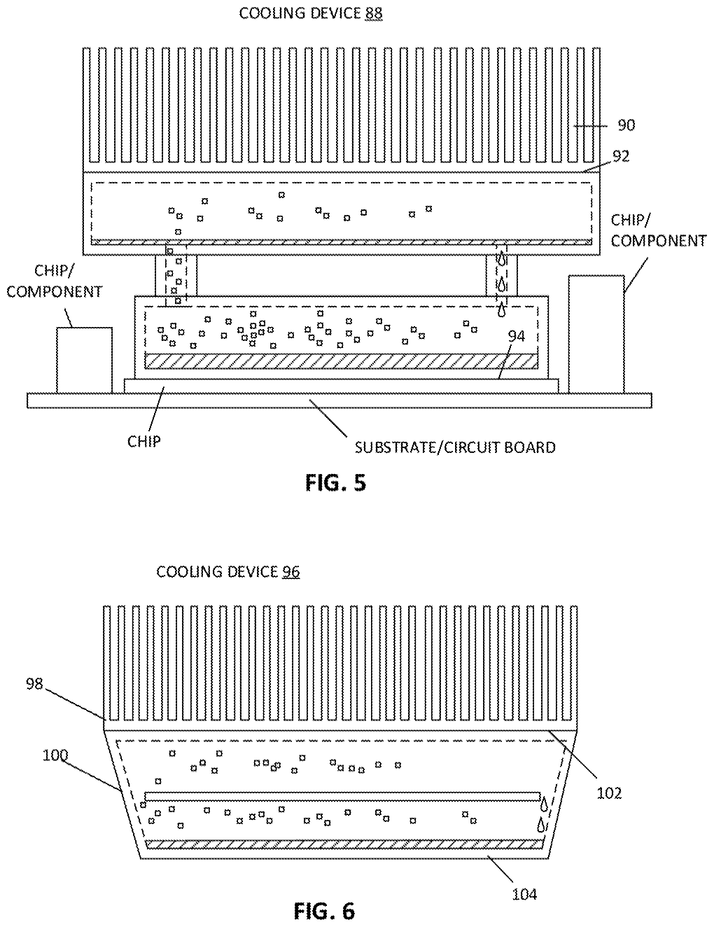

For example, FIG. 5 shows a cooling device 88 connected to a chip at a bottom surface 94 of the cooling device. The top housing can have a top surface 92 that connects to cooling member 90, where the top surface 92 is greater in area than the bottom surface 94. Thus, the heat transferred from the chip to the cooling member is not limited by the footprint of the chip.

In addition, especially in the latest heterogeneous integration cases, packaging and electronic constraints often requires a high density power item to be located near other chips or components that are tall, which can provide an obstacle for heat transfer from the high density power item (see the adjacent components in FIG. 5). In this case, the lower portion or evaporation portion can provide a platform to elevate over tall adjacent components and still transfer heat away from the high density power item, as shown in FIG. 5.

Similarly, as shown in FIG. 6, a cooling device 96 has an evaporation chamber and condensing chamber in the same body. In this case, the evaporation portion (or top surface 102) is larger, or ‘enhanced’ relative to the footprint or bottom surface 104 of the cooling device. For example, walls 100 can project outward resulting in a trapezoidal shape. This also represents an example that the whole cooling device is design as one single unit.

### ColdPlate

In one aspect, as shown in FIG. 7, a cooling member can include a cold plate 116 that has a liquid dispersed in one or more cold plate channels. The liquid can circulate to and from the cold plate during operation to remove heat from the cooling device. The liquid can be circulated, for example, by an external pump, not shown in the drawing. It should be understood that the cooling liquid in the cold plate is physically separate and isolated from the fluid in evaporation and condensing chamber. The channel or channels of the cold plate can be a zig-zag or meandering path. In one aspect, the channels are created by space between fins 110 of the cold plate. Cold plate designs can vary based on application and can be determined through routine testing.

### Geometry

The housings and cooling members of the cooling device can have geometries that are substantially rectangular, circular, square, or other shapes. Similarly, the channels can be round, rectangular, or have other shapes. The geometry of the device can be determined based on routine experimentation and based on the application, for example, based on a footprint of a particular chip.

For example, a bottom surface of the cooling device can be shaped and sized substantially similar to a packaged electronic chip to maximize surface contact to the chip. The bottom surface can be substantially flat, like a typical chip. Chips come in various form factors, shapes and sizes.

### Producing a Cooling Device

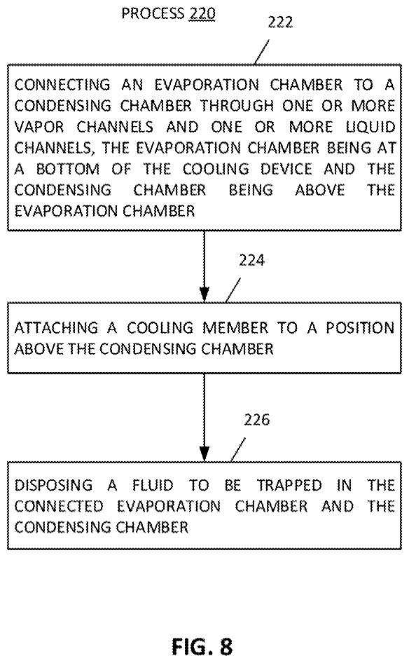

In one aspect of the present disclosure, a process 220 is shown in FIG. 8 for producing a cooling device. The process includes, at block 222, connecting an evaporation chamber to a condensing chamber through one or more vapor channels and one or more liquid channels, the evaporation chamber being at a bottom of the cooling device and the condensing chamber being above the evaporation chamber.

The process further includes, at block 224, attaching a cooling member to a position above the condensing chamber. The cooling member can be an air-cooled plate, for example, having one or more fins. In some aspects, the cooling member can include a liquid cooling plate having one or more channels with a cooling liquid disposed within.

The process further includes, at block 226, disposing or filling a fluid to be trapped in the connected evaporation chamber and the condensing chamber. During operation of the cooling device, the fluid undergoes phase changes due to heat transfer, vapor travels up the one or more vapor channels into the condensing chamber and liquid travels down the one or more liquid channels to the evaporation chamber. In one aspect, the connected chambers are hermetically sealed so that the fluid (vapor and liquid) does not escape and pressure does not escape the connected chambers.

FIG. 8 shows one example of the producing procedure for the cooling device. Other type of manufacturing processes can be implemented for producing a cooling device of the present disclosure.

Note that a chip device attached to a bottom of any of the cooling devices as described above can be any information technology (IT) component or element that when operates, generates heat. A chip device can be a processor, a field programmable gate array (FPGA), an application specific integrated circuit (ASIC), or any computing components. A device can be one of the devices within any one of one or more servers of an electronic rack of a data center. A server may be contained within a server blade which is inserted into one of the server slots of an electronic rack. Each server includes a processor, a memory, a storage device, and a network interface that are configured to provide data processing services to clients. Such components may generate heat during normal operations. Also note that heat exchanger 30 (e.g., heatsink as shown in this example) can be a cold plate using liquid cooling, in which liquid-to-liquid heat exchange is performed using a rack cooling unit, a room cooling unit, and/or a datacenter cooling unit.

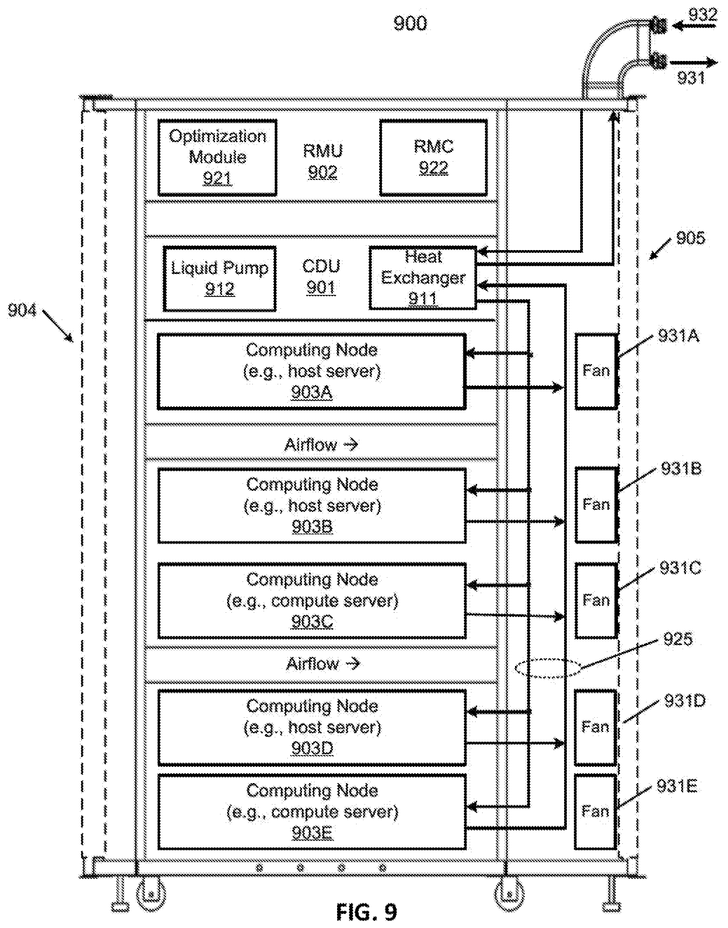

FIG. 9 is a block diagram illustrating an example of an electronic rack according to one embodiment. Electronic rack 900 may contain one or more servers, each server having one or more processing units attached to a bottom of any of the cooling devices described above. Referring to FIG. 9, according to one embodiment, electronic rack 900 includes, but is not limited to, CDU 901, rack management unit (RMU) 902 (optional), and one or more server blades 903A-903E (collectively referred to as server blades 903). Server blades 903 can be inserted into an array of server slots respectively from frontend 904 or backend 905 of electronic rack 900. Note that although there are only five server blades 903A-903E shown here, more or fewer server blades may be maintained within electronic rack 900. Also note that the particular positions of CDU 901, RMU 902, and server blades 903 are shown for the purpose of illustration only; other arrangements or configurations of CDU 901, RMU 902, and server blades 903 may also be implemented. Note that electronic rack 900 can be either open to the environment or partially contained by a rack container, as long as the cooling fans can generate airflows from the frontend to the backend.

In addition, for each of the server blades 903, a fan module is associated with the server blade. In this embodiment, fan modules 931A-931E, collectively referred to as fan modules 931, are associated with server blades 903A-903E respectively. Each of the fan modules 931 includes one or more cooling fans. Fan modules 931 may be mounted on the backends of server blades 903 to generate airflows flowing from frontend 904, traveling through the air space of the sever blades 903, and existing at backend 905 of electronic rack 900.

In one embodiment, CDU 901 mainly includes heat exchanger 911, liquid pump 912, and a pump controller (not shown), and some other components such as a liquid reservoir, a power supply, monitoring sensors and so on. Heat exchanger 911 may be a liquid-to-liquid heat exchanger. Heat exchanger 911 includes a first loop with inlet and outlet ports having a first pair of liquid connectors coupled to external liquid supply/return lines 931-932 to form a primary loop. The connectors coupled to the external liquid supply/return lines 931-932 may be disposed or mounted on backend 905 of electronic rack 900. The liquid supply/return lines 931-932 are coupled to a set of room manifolds, which are coupled to an external heat removal system, or extremal cooling loop. In addition, heat exchanger 911 further includes a second loop with two ports having a second pair of liquid connectors coupled to liquid manifold 925 to form a secondary loop, which may include a supply manifold to supply cooling liquid to server blades 903 and a return manifold to return warmer liquid back to CDU 901. Note that CDUs 901 can be any kind of CDUs commercially available or customized ones. Thus, the details of CDUs 901 will not be described herein. As an example, cooling device 108 shown in FIG. 7 may connect to 925 to complete a full fluid loop.

Each of server blades 903 may include one or more IT components (e.g., central processing units or CPUs, graphical processing units (GPUs), memory, and/or storage devices). Each IT component may perform data processing tasks, where the IT component may include software installed in a storage device, loaded into the memory, and executed by one or more processors to perform the data processing tasks. At least some of these IT components may be attached to the bottom of any of the cooling devices as described above. Server blades 903 may include a host server (referred to as a host node) coupled to one or more compute servers (also referred to as computing nodes, such as CPU server and GPU server). The host server (having one or more CPUs) typically interfaces with clients over a network (e.g., Internet) to receive a request for a particular service such as storage services (e.g., cloud-based storage services such as backup and/or restoration), executing an application to perform certain operations (e.g., image processing, deep data learning algorithms or modeling, etc., as a part of a software-as-a-service or SaaS platform). In response to the request, the host server distributes the tasks to one or more of the performance computing nodes or compute servers (having one or more GPUs) managed by the host server. The performance compute servers perform the actual tasks, which may generate heat during the operations.

Electronic rack 900 further includes optional RMU 902 configured to provide and manage power supplied to servers 903, fan modules 931, and CDU 901. RMU 902 may be coupled to a power supply unit (not shown) to manage the power consumption of the power supply unit. The power supply unit may include the necessary circuitry (e.g., an alternating current (AC) to direct current (DC) or DC to DC power converter, backup battery, transformer, or regulator, etc.,) to provide power to the rest of the components of electronic rack 900.

In one embodiment, RMU 902 includes optimization module 921 and rack management controller (RMC) 922. RMC 922 may include a monitor to monitor operating status of various components within electronic rack 900, such as, for example, computing nodes 903, CDU 901, and fan modules 931. Specifically, the monitor receives operating data from various sensors representing the operating environments of electronic rack 900. For example, the monitor may receive operating data representing temperatures of the processors, cooling liquid, and airflows, which may be captured and collected via various temperature sensors. The monitor may also receive data representing the fan power and pump power generated by the fan modules 931 and liquid pump 912, which may be proportional to their respective speeds. These operating data are referred to as real-time operating data. Note that the monitor may be implemented as a separate module within RMU 902.

Based on the operating data, optimization module 921 performs an optimization using a predetermined optimization function or optimization model to derive a set of optimal fan speeds for fan modules 931 and an optimal pump speed for liquid pump 912, such that the total power consumption of liquid pump 912 and fan modules 931 reaches minimum, while the operating data associated with liquid pump 912 and cooling fans of fan modules 931 are within their respective designed specifications. Once the optimal pump speed and optimal fan speeds have been determined, RMC 922 configures liquid pump 912 and cooling fans of fan modules 931 based on the optimal pump speed and fan speeds.

As an example, based on the optimal pump speed, RMC 922 communicates with a pump controller of CDU 901 to control the speed of liquid pump 912, which in turn controls a liquid flow rate of cooling liquid supplied to the liquid manifold 925 to be distributed to at least some of server blades 903. Therefore, the operating condition and the corresponding cooling device performance is adjusted. Similarly, based on the optimal fan speeds, RMC 922 communicates with each of the fan modules 931 to control the speed of each cooling fan of the fan modules 931, which in turn control the airflow rates of the fan modules 931. Note that each of fan modules 931 may be individually controlled with its specific optimal fan speed, and different fan modules and/or different cooling fans within the same fan module may have different optimal fan speeds.

Note that some or all of the IT components of servers 903 may be attached to any one of the cooling devices described above, either via air cooling using a heatsink or via liquid cooling using a cold plate. One server may utilize air cooling while another server may utilize liquid cooling. Alternatively, one IT component of a server may utilize air cooling while another IT component of the same server may utilize liquid cooling.

It should be understood that the various features shown with respect to one figure can also be present in other embodiments of different features. For example, the wicking structure shown in FIGS. 3 and 4 can also be present in the embodiments shown in any of the other figures. Similarly, the cold plate with active liquid circulation shown in FIG. 7 can be used with the other embodiments of FIGS. 1-6. Similarly, each of the embodiments can have a condenser with enhanced area, and each of the condensers can have sloped floor geometry.

In the foregoing specification, embodiments of the invention have been described with reference to specific exemplary embodiments thereof. It will be evident that various modifications may be made thereto without departing from the broader spirit and scope of the invention as set forth in the following claims. The specification and drawings are, accordingly, to be regarded in an illustrative sense rather than a restrictive sense.

What is claimed is:

1. A cooling device comprising:
an evaporation chamber in fluid connection with a condensing chamber through one or more vapor channels and one or more liquid channels, the evaporation chamber being at a bottom of the cooling device and the condensing chamber being above the evaporation chamber;
a cooling member being thermally connected to and located above the condensing chamber; and
a fluid disposed in the connected evaporation chamber and the condensing chamber to undergo phase changes due to heat transfer, wherein vapor travels up the one or more vapor channels into the condensing chamber and liquid travels down the one or more liquid channels to the evaporation chamber during operation.

2. The cooling device of claim 1, wherein:
the evaporation chamber is formed in a first housing,
the condensing chamber is formed in a second housing,
the one or more vapor channels are formed in one or more vapor pipes,
the one or more liquid channels are formed in one or more liquid pipes,
the first housing and the second housing are connected through the one or more vapor pipes and the one or more liquid pipes,
and the cooling member is fixed to a top surface of the second housing.

3. The cooling device of claim 2, wherein the top surface of the second housing is larger in area than a bottom surface of the first housing, increasing heat transfer performance from the condensing chamber to the attached cooling member.

4. The cooling device of claim 1, wherein
the evaporation chamber and the condensing chamber are formed in a single body being separated by a separation wall within the single body,
the one or more vapor channels and the one or more liquid channels are formed by openings or gaps in the separation wall, and
the cooling member is fixed to a top surface of the single body.

5. The cooling device of claim 4, wherein the top surface of the single body is larger in area than a bottom surface of the single body, increasing an amount of heat that can transfer from the condensing chamber to the attached cooling member.

6. The cooling device of claim 1, wherein the cooling member has one or more fins that provide additional surface area to remove and transfer heat from the cooling device through air cooling.

7. The cooling device of claim 6, wherein the one or more fins are flat shaped members that are arranged substantially parallel to each other.

8. The cooling device of claim 1, wherein the cooling member is a cold plate that has liquid dispersed in one or more cold plate channels, the liquid circulating to and from the cold plate during operation to remove heat from the cooling device.

9. The cooling device of claim 1, wherein the condensing chamber has a floor that is horizontally tilted such that an opening of the one or more vapor channels is higher than an opening of the one or more liquid channels.

10. The cooling device of claim 1, wherein the cooling device includes a porous wick structure disposed in the evaporation chamber.

11. The cooling device of claim 10, wherein the porous wick structure is further disposed in the one or more liquid channels.

12. The cooling device of claim 1, wherein the cooling device has a bottom surface shaped and sized substantially similar to a packaged electronic chip to maximize surface contact to the packaged electronic chip.

13. The cooling device of claim 12, wherein the bottom surface is substantially flat.

14. The cooling device of claim 1, wherein each of the one or more vapor channels are larger in cross section or diameter than each of the one or more liquid channels.

15. An article of manufacture comprising:
an evaporation chamber in fluid connection with a condensing chamber through one or more vapor channels and one or more liquid channels, the evaporation chamber being at a bottom of the article of manufacture and the condensing chamber being above the evaporation chamber;
a cooling member being thermally connected to and located above the condensing chamber; and
a fluid disposed in the connected evaporation chamber and the condensing chamber to undergo phase changes due to heat transfer, wherein vapor travels up the one or more vapor channels into the condensing chamber and liquid travels down the one or more liquid channels to the evaporation chamber during operation.

16. The cooling device of claim 15, wherein:
the evaporation chamber is formed in a first housing,
the condensing chamber is formed in a second housing,
the one or more vapor channels are formed in one or more vapor pipes,
the one or more liquid channels are formed in one or more liquid pipes,
the first housing and the second housing are connected through the one or more vapor pipes and the one or more liquid pipes, and
the cooling member is fixed to a top surface of the second housing.

17. The cooling device of claim 16, wherein the top surface of the second housing is larger in area than a bottom surface of the first housing, increasing heat transfer performance from the condensing chamber to the attached cooling member.

18. The cooling device of claim 15, wherein
the evaporation chamber and the condensing chamber are formed in a single body being separated by a separation wall within the single body,
the one or more vapor channels and the one or more liquid channels are formed by openings or gaps in the separation wall, and
the cooling member is fixed to a top surface of the single body.

19. The cooling device of claim 15, wherein
the evaporation chamber, the condensing chamber, and the cooling member are formed in a single body, the evaporation chamber and the condensing chamber being separated by a separation wall within the single body, and
the one or more vapor channels and the one or more liquid channels are formed by openings or gaps in the separation wall.

20. A method for producing a cooling device, comprising:
connecting an evaporation chamber to a condensing chamber through one or more vapor channels and one or more liquid channels, the evaporation chamber being at a bottom of the cooling device and the condensing chamber being above the evaporation chamber;
attaching a cooling member to a position above the condensing chamber; and
disposing a fluid to be trapped in the connected evaporation chamber and the condensing chamber,
wherein, during operation of the cooling device,
the fluid undergoes phase changes due to heat transfer,
vapor travels up the one or more vapor channels into the condensing chamber and liquid travels down the one or more liquid channels to the evaporation chamber.
